(19) United States
(12) Patent Application Publication
(10) Pub. No.: US 2009/0195344 A1
(43) Pub. Date: Aug. 6, 2009

(54) CONTACTLESS DATA COMMUNICATIONS COUPLER

(75) Inventors: Dennis Marvel, Boca Raton, FL (US); Jurgen Kruppa, Delray Beach, FL (US); Anthony Lang, Delray Beach, FL (US)

Correspondence Address: GOODWIN PROCTER LLP;PATENT ADMINISTRATOR, 53 STATE STREET, EXCHANGE PLACE, BOSTON, MA, 02109-2881, US

(73) Assignee: Kinkisharyo International, LLC, Canton, MA (US)

(21) Appl. No.: 12/159,916

(22) PCT Filed: Jan. 6, 2007
(86) PCT No.: PCT/US07/60198

§ 371 Date: Jan. 9, 2009

(30) Foreign Application Priority Data
Jan. 6, 2006 (US) 60757046
Jul. 7, 2006 (US) PCT/US2006/026672

(51) Int. Cl. H01F 19/04; H03H 7/38

(52) U.S. Cl. 336/200; 333/32

(57) ABSTRACT

The embodiments of the present invention provide a non-contact data connection that is adaptable to transmit data across an air gap. The data connection includes a first substrate (706) and a loosely coupled wide band pulse transformer for transmitting data over an air gap (820) separating a primary-winding (704) from a secondary winding (714) of the transformer. The primary winding of the transformer includes at least two planar windings formed in parallel planes upon and/or within the first substrate for facilitating a neutralization of transmission line resonances due to distributed capacitance and inductance of the planar windings.

### CROSS-REFERENCE TO RELATED APPLICATIONS

This application is related to and claims priority from provisional patent application entitled CONTACTLESS DATA COMMUNICATIONS COUPLER, filed on Jan. 7, 2006 and assigned Ser. No. 60/757,046, the entire disclosure of which is herein incorporated by reference. Further this application is related to and claims priority of a PCT application entitled CONTACTLESS DATA COMMUNICATIONS COUPLER IN A TRAIN COUPLING ENVIRONMENT METHOD AND SYSTEM, filed Jul. 7, 2006, and assigned Ser. No. PCT/US06/26672, which is related to and claims priority from provisional application entitled CONTACTLESS DATA COMMUNICATIONS COUPLER IN A TRAIN COUPLING ENVIRONMENT METHOD AND SYSTEM, filed Jul. 7, 2005, and assigned Ser. No. 60/697,317, and which application is hereby fully incorporated by reference herein.

### FIELD OF THE INVENTION

This invention generally relates to the field of contact-less data signal coupling and more specifically to the field of contact-less data signal coupling mechanisms optimized for wide band communications over an air gap.

### DESCRIPTION OF THE RELATED ART

This invention generally relates to the field of contact-less data signal coupling and more specifically to the field of contact-less data signal coupling mechanisms optimized for a train coupling environment.

Electrical couplings between railroad cars, such as tram or railway cars, are generally limited to conveying electrical power or low bandwidth data signals. There is an increasing need to provide higher speed data communications between railroad cars that are connected together. A desire to provide, for example, real time video observation of the interior of one or more rail cars, real time observation of a multitude of system monitoring data values and other data communications among the multiple cars of a rail train have increased the required data rate for data transmissions around a rail car to be greater than 50 megabits per second and sometimes to greater than 90 megabits/second. The physical size, structure and environment of railroad couplers generally limits the ability to achieve such high data rate transfers over connections that are incorporated into quick disconnect couplings. Alternative methods of achieving high bandwidth data transfer between railroad cars include using RF communications. RF communications, however, are subject to interference and cross-talk between different trains and require unique addressing of all cars used in a railway to ensure proper communication connections among only rail cars that are in the same train.

Railroad cars, including trams, streetcars and light rail cars (hereinafter “cars”), are generally connected together by mechanical couplers. An electrical coupler head (hereinafter “head”), which comprises a box-like electrical insulator, is mounted to each mechanical coupler. The electrical insulator of the head has a plurality of approximately 0.375-inch diameter cylindrical openings for acceptance of metallic pins. Known electrical couplings for electrical power or low bandwidth data signals are generally accomplished through the use of ohmic contact between corresponding pins of two heads, each head mounted to a pair of coupled mechanical couplers. Without intensive signal conditioning, such electrical couplings are limited to conveying electrical power or low bandwidth data signals of less than one megabit per second because of a large difference between the impedance of high-speed data cable and the impedance of the pins and of the junction between the pins. Such coarse pin connections are also subject to electrical radiation and interference due to the large spacings between adjacent pins of a head. An electrical coupling through the use of pins is considered a quick-disconnect coupling, in that the electrical coupling is quickly broken when the mechanical couplers are uncoupled.

### SUMMARY OF THE INVENTION

The subject matter, which is regarded as the invention, is particularly pointed out and distinctly claimed in the claims at the conclusion of the specification. The foregoing and other features, and advantages of the invention will be apparent from the following detailed description taken in conjunction with the accompanying drawings.

The embodiments of the present invention provide a non-contact data connection that is adaptable to transmit data across an air gap. The data connection includes a first substrate and a loosely coupled wide band pulse transformer for transmitting data over an air gap separating a primary winding from a secondary winding of the transformer. The primary winding of the transformer includes at least two planar windings formed in parallel planes upon and/or within the first substrate for facilitating a neutralization of transmission line resonances due to distributed capacitance and inductance of the planar windings.

These embodiments utilize a primarily magnetic field coupling to communicate either baseband data or RF signals through a quick-disconnect electrical coupling device that can be easily mounted in an electrical coupler head.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention will be apparent from the following detailed description taken in conjunction with the accompanying drawings, in which:

FIG. 1 is a cross-sectional view of a portion of two electrical coupler heads incorporating signal coupling units according to exemplary embodiments of the present invention;

FIG. 2 is an inter-car network architecture using baseband inter-car coupling units according to a first exemplary embodiment of the present invention;

FIG. 3 is an inter-car network architecture using RF based inter-car coupling units according to a second exemplary embodiment of the present invention;

FIGS. 4 and 5 are a block diagram of a non-contact Ethernet baseband coupling system;

FIG. 6 is a graph of frequency response for the non-contact Ethernet baseband coupling system of FIG. 4;

FIG. 7 is a front view illustrating one embodiment of the sender and receiver;

FIG. 8 is side view of the receiver printed circuit board and the sender printed circuit board of FIG. 7;

FIG. 9 show is a side view of the sender and receiver of FIG. 7;

FIG. 10 a perspective view of FIGS. 7 and 9 illustrating how the two-layer printed spiral winding of the sending unit cause wavelet cancellation at the midpoint where a resistor is disposed;

FIG. 11 shows a low- to mid-frequency equivalent circuit of the transformer with the admittance equalization network added; and

FIG. 12 shows the general circuit topology.

### DETAILED DESCRIPTION OF AN EMBODIMENT

It should be understood that these embodiments are only examples of the many advantageous uses of the innovative teachings herein. In general, statements made in the specification of the present application do not necessarily limit any of the various claimed inventions. Moreover, some statements may apply to some inventive features but not to others. In general, unless otherwise indicated, singular elements may be in the plural and vice versa with no loss of generality.

This application incorporates by reference each of the following three references each in their entirety: i) provisional patent application entitled CONTACTLESS DATA COMMUNICATIONS COUPLER, filed on Jan. 7, 2006 and assigned Ser. No. 60/757,046; ii) PCT application entitled CONTACTLESS DATA COMMUNICATIONS COUPLER IN A TRAIN COUPLING ENVIRONMENT METHOD AND SYSTEM, filed Jul. 7, 2006, and assigned Ser. No. PCT/US06/26672; and iii) provisional application entitled CONTACTLESS DATA COMMUNICATIONS COUPLER IN A TRAIN COUPLING ENVIRONMENT METHOD AND SYSTEM, filed Jul. 7, 2005, and assigned Ser. No. 60/697,317.

As required, detailed embodiments of the present invention are disclosed herein; however, it is to be understood that the disclosed embodiments are merely examples of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

The terms “a” or “an”, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly, and not necessarily mechanically. The term signal, control, threshold are any electrical, magnetic, optical, biological, chemical or combination thereof to convey information to a analog or digital input.

Exemplary embodiments of the present invention utilize one of two different approaches for transferring high-speed data across two coupled cars using a signal coupling system that neither requires nor uses ohmic contact between the cars. Each approach is able to carry, for example, 100-Mbit/sec Ethernet signals from one car to another across signal coupling units that are easily incorporated into a head of a mechanical train coupler. The first of these approaches directly couples the Ethernet baseband signal through custom-designed magnetics within each signal coupling unit that are used in combination with specialized active signal conditioning circuitry of the system. This approach is capable of full-duplex Ethernet communication at 100-Mbits/sec. The second of these approaches incorporates an intermediate conversion to a radio frequency (RF) signal, such as an IEEE 802.11a wireless format, that operates in the vicinity of 5-GHz. The RF signal is transmitted across the signal coupling units through a specially designed short-range, near-field antenna-like coupling arrangement within each signal coupling unit. The RF approach is limited to half-duplex operation at 54-Mbits/sec (with standard equipment) or 108-Mbits/sec (with special non-standard equipment) in one direction at a time.

Overview of Two Heads

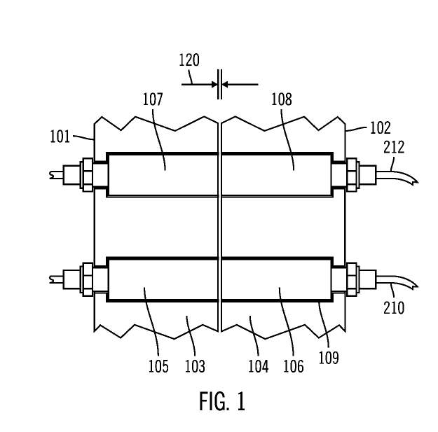

FIG. 1 is a cross-sectional view of a portion of two heads 101 and 102. Each head, 101 and 102, which includes an electrical insulator 103 and 104, respectively, is mounted to a mechanical coupler (not shown) of a car. At least one signal coupling unit according to exemplary embodiments of the present invention is mounted in each head 101 and 102. There are two types of signal coupling units, non-contact sending units 105 and 108 and non-contact receiving units 106 and 107. Each signal coupling unit includes electrical coupling components contained within a pin-shaped metallic housing 109 enclosing at least the primary windings except at a region from which the magnetic field is generated across the air gap 120 separating each sending-receiver unit pair 103, 104 and 108, 107 respectively. The housing 109 is easily mountable within a cylindrical mounting opening in the head 101 and 102. In one exemplary embodiment, the outer diameter of the housing is 0.7-inch, and because the outer diameter of the housing 109 is slightly larger than the outer diameter of a prior art pin, the diameter of the cylindrical mounting opening assigned to the housing is enlarged appropriately. Each signal coupling unit replaces a prior art pin. One non-contact sending unit 105 on a car is paired, or mated to, one non-contact receiving unit 106 on an adjacent, coupled car. In FIG. 1, head 101 has one non-contact sending unit 105 and one non-contact receiving unit 107, and head 102 has one non-contact receiving unit 106 and one non-contact sending unit 108. Sending unit 108 mates with receiving unit 107 and they constitute a pair. Sending unit 105 mates with receiving unit 106 and they constitute another pair. A gap 120 appears between the non-contact sending unit 108 that is mounted in head 102 and the non-contact receiving unit 107 that is mounted in head 101. The gap 120 also appears between the non-contact receiving unit 106 that is mounted in head 102 and the non-contact sending unit 105 that is mounted in head 101. In one embodiment, the gap 120 can range from 0 to 150-thousandths of an inch without substantially affecting the data error rate. It is important to note that the gap 120 in other embodiments can be larger than 150 thousands with extra gain and with a slightly higher rate. The signal coupling units of the invention, unlike prior art pins, do not come into physical contact with its mate on an adjoining car. Only an electromagnetic field bridges the gap 120 between paired signal coupling units. The above statements apply to the baseband coupling approach. With the RF coupling approach, the distinction between sender and receiver vanishes, and only one pair of special pins (e.g., 105 and 106) is required to carry the signal. This distinction comes about because of the half-duplex nature of any single radio channel.

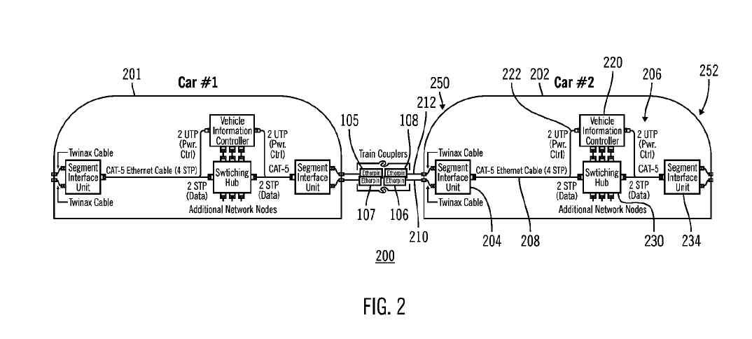

Referring now to FIGS. 1 and 2, the top pair of facing signal coupling units, non-contact sending unit 108 and non-contact receiving unit 107, carries data from a car 202 on the right to a car 201 on the left, while the bottom pair of signal coupling units carries data in the opposite direction. Two pairs of signal coupling units are used in the Ethernet baseband approach, which provides full-duplex communications. Only one pair of signal coupling units is used in the second approach, which converts to RF signal, resulting in half-duplex operations.

Network Architecture For Ethernet Baseband

FIG. 2 illustrates a network architecture 200 coupling car 201 with car 202 of a consist, which network architecture incorporates non-contact Ethernet baseband signal coupling, according to a first exemplary embodiment of the invention. A segment interface or base unit 204 is contained in a small box located within each car 201 and 202, and includes active circuitry that provides the correct signal amplitude and termination impedance for an intra-car Local Area Network (LAN) 206 wired in each car using conventional category-5 (CAT-5) or CAT-5E Ethernet cable. The segment unit interface or base unit 204 acts as an interface to the Ethernet LAN cable, provides further amplification of transmitted and received signals, and contains the initial stage of the equalization network for transmitted signals. Power is furnished to the trainline interface unit or base unit or segment interface unit 204 by means of surplus twisted wire pairs contained inside a CAT-5 cable 208. The segment interface unit 204 furnishes power to the non-contact receiving unit 106 and the non-contact sending unit 108 at a first end 250 of the car 202. A cable 210 and 212 connects the segment interface unit 204 to the non-contact receiving unit 106 and to the non-contact sending unit 108, respectively. In one embodiment cable 210 and 212 is twinax but other types of cables have been show to be used advantageously with the present invention. There are no other connectors on the segment interface unit 204 in this embodiment other than those required for the cables shown in the diagram. The segment interface unit 204 is coupled to a vehicle information controller 220. The vehicle information controller 220 acts as a controlling intelligence behind the subsystems that share data over the LAN 206. The vehicle information controller 220 is coupled to a switching hub 230 and to a second segment interface unit 234. The second segment interface unit 234 is coupled to a second set of non-contact coupling units (not shown) at a second end 252 of the car 202. The switching hub provides a place to couple the various devices that communicate over the LAN 206, and intelligently routing Ethernet frames according to their source and destination addresses. The segment interface unit 204 is part of the LAN 206, although it is not, strictly speaking, an Ethernet device. The segment interface unit 204 carries the Ethernet signal but does not have a media access control address of its own.

Network Architecture for RF Signal Coupling

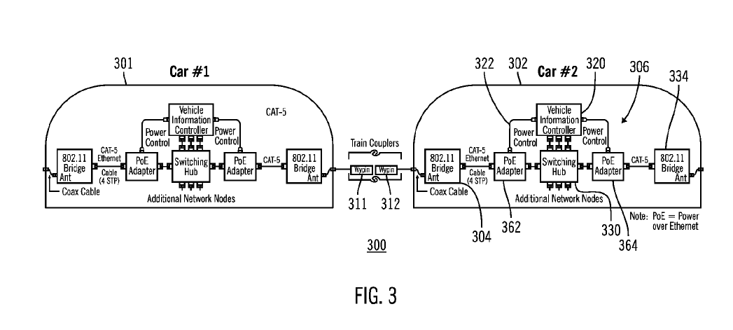

FIG. 3 illustrates a network architecture 300 coupling car 301 with car 302 of a consist, which network architecture incorporates RF signal coupling according to a wireless network standard such as IEEE 802.11. The RF-based network architecture 300 includes a LAN 306. The RF-based network architecture 300 has several similarities to the Ethernet baseband network architecture 200 illustrated in FIG. 2, but the trainline interface unit, base unit or segment interface unit 204 is replaced by a wireless network bridge 304 and the twinax 210 is replaced by a high-frequency coax 310. The wireless network bridge 304 includes an RF transceiver and a network adaptor. Another difference is that the RF-based network architecture 300 includes power-over-Ethernet adapters 362 and 364 that are coupled to the vehicle information controller 320, to the switching hub 330, and to the wireless network bridge and second wireless network bridge 334. The power-over-Ethernet adapters 362 and 364 place 48V DC on one of the unused twisted pairs in the CAT-5 cable, to deliver power to devices (such as the 802.11 bridge) that communicate over the LAN 306 while drawing their power from the LAN, according to IEEE standard 802.3af. Inside each signal coupling unit 311 and 312 is a high-frequency, near-field antenna (not shown).

In both the Ethernet baseband network architecture 200 and RF-based network architecture 300, a control signal 222 and 322 enables a vehicle information controller 220 and 320, respectively, to disable the wireless coupling of the system at one or both ends of the car 202 and 302. This feature prevents unintentional radiation of signals from an uncoupled end of the car 202 and 302, and also aids in consist enumeration.

System Schematic for Ethernet Baseband

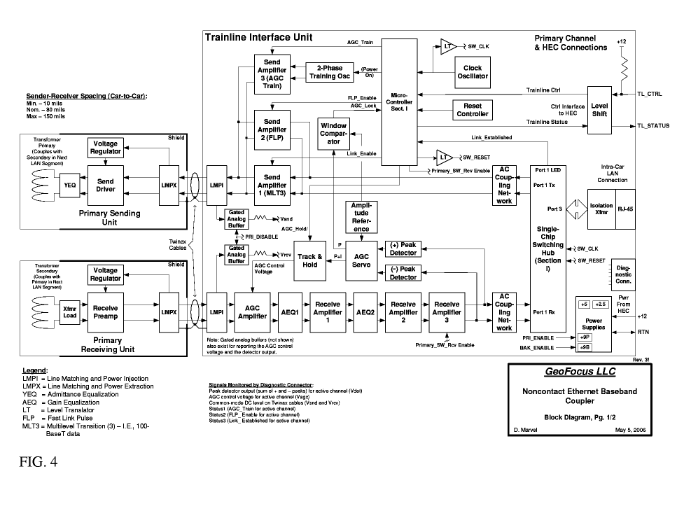

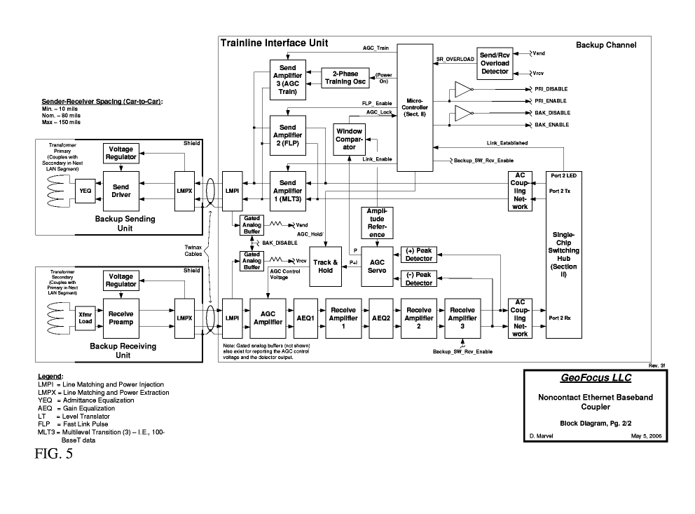

FIG. 4 and FIG. 5 illustrate block diagrams of components that form a non-contact Ethernet baseband coupling system The blocks labeled Primary Sending Unit and Primary Receiving Unit (FIG. 4) represent the coupler-mounted hardware, including the transformer windings, local amplifiers (called Send Driver and Receive Preamp), and circuitry for extracting the operating power supplied as a common-mode DC voltage on the differential (Twinax) cable. The word Primary, as used here, signifies the default transmission channel and does not refer to the primary winding of the transformer. The blocks labeled Backup Sending Unit and Backup Receiving Unit (FIG. 5) represent the corresponding coupler-mounted hardware for the backup transmission channel (used when there is a failure on the primary channel). The block diagrams also contain representations of the admittance equalizing network (labeled YEQ) for the transformer primary winding inside the sender unit for each channel. Other features shown are the AGC mechanism (consisting of the AGC amplifier, Track and Hold, AGC Servo, and Peak Detectors), and the gain equalization networks (labeled AEQ1 and AEQ2). These functional blocks are duplicated in the circuitry for each channel. Finally, the block diagrams show the single-chip switching hub used to provide a standardized interface to the Ethernet LAN. This interface device also provides store-and-forward service for the Ethernet data frames passed through the network.

Frequency Response

FIG. 6 is a graph 600 of a frequency domain transfer function for a signal coupled through the Ethernet baseband coupling of the first exemplary embodiment of the present invention. The x-axis signifies frequency. The left y-axis signifies magnitude. The right y-axis signifies phase. In FIG. 68, four curves are shown. They are: a “V(out), magnitude” 601, which is a simulated magnitude of the output of the receive amplifier in the segment interface unit; a “V(out), phase” 602, which is a simulated phase of the output of the receive amplifier in the segment interface unit 204; a “V(x4s+), phase”, which is a simulated phase of the output of a cascaded pair of packaged commercial Ethernet transformers; and a “V(x4s+), magnitude”, which is a simulated magnitude of output of a cascaded pair of packaged commercial Ethernet transformers. The simulated outputs of the packaged commercial Ethernet transformer are shown for comparison purposes. The contactless data communications coupling system of the invention has successfully coupled an Ethernet baseband signal through an air gap of up to 150-thousandths of an inch. FIG. 6 illustrates that the frequency response 601 and 602 for the contactless data communications coupling system of the invention advantageously closely approximates the coupling characteristics of a prior art Ethernet transformer pair. In FIG. 6, the curve labeled “V(out), mag” is a frequency-domain representation of the voltage presented to the switch chip receive terminals, normalized to the standard line amplitude for 100 Base-TX as defined in IEEE 802.3. The AGC circuit regulates the received signal at this amplitude over a wide range of air gap values. It should be noted that the size of the gap 120 across which the contactless data communications coupling system of the invention can successfully couple an Ethernet signal is dependent, in part, on the diameter of the winding, and increases as the diameter increases. The transmission distance can also be increased by adding gain to the receive amplifier chain in the segment interface unit.

Frequency Response

FIG. 8 is a graph 600 of a frequency domain transfer function for a signal coupled through the Ethernet baseband coupling of the first exemplary embodiment of the present invention. The x-axis signifies frequency. The left y-axis signifies magnitude. The right y-axis signifies phase. In FIG. 68, four curves are shown. They are: a “V(out), magnitude” 601, which is a simulated magnitude of the output of the receive amplifier in the segment interface unit; a “V(out), phase” 602, which is a simulated phase of the output of the receive amplifier in the segment interface unit 204; a “V(x4s+), phase”, which is a simulated phase of the output of a cascaded pair of packaged commercial Ethernet transformers; and a “V(x4s+), magnitude”, which is a simulated magnitude of output of a cascaded pair of packaged commercial Ethernet transformers. The simulated outputs of the packaged commercial Ethernet transformer are shown for comparison purposes. The contactless data communications coupling system of the invention has successfully coupled an Ethernet baseband signal through an air gap of up to 50-thousandths of an inch, and it may be possible to couple an Ethernet baseband signal through an air gap of up to 150-thousandths of an inch. FIG. 6 illustrates that the frequency response 601 and 602 for the contactless data communications coupling system of the invention advantageously closely approximates the coupling characteristics of a prior art Ethernet transformer pair. It should be noted that the size of the gap 120 across which the contactless data communications coupling system of the invention can successfully couple an Ethernet signal is dependent, in part, to the diameter of the winding, and increases as the diameter increases. The transmission distance can also be increased by adding gain to the receive amplifier chain in the segment interface unit and by adding an automatic gain control (not shown).

Advantageously, once the cars of a consist, such as cars 201 and 202, are joined together and the network devices in various cars have found one another and established communications, a train-wide network is formed and effectively functions as a single LAN.

Details of Contactless Data Communication Coupler

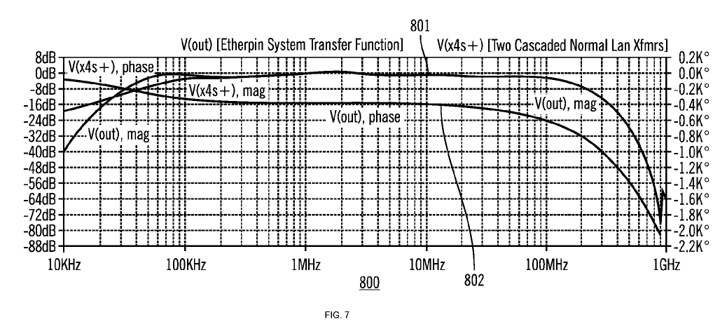

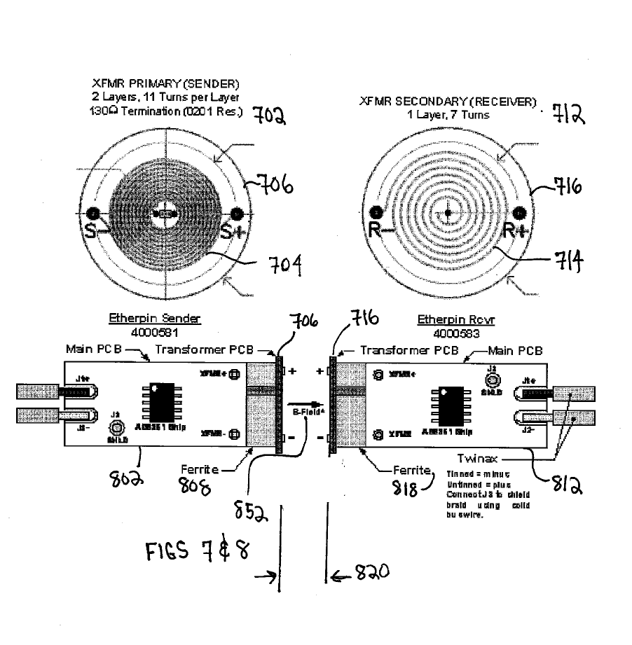

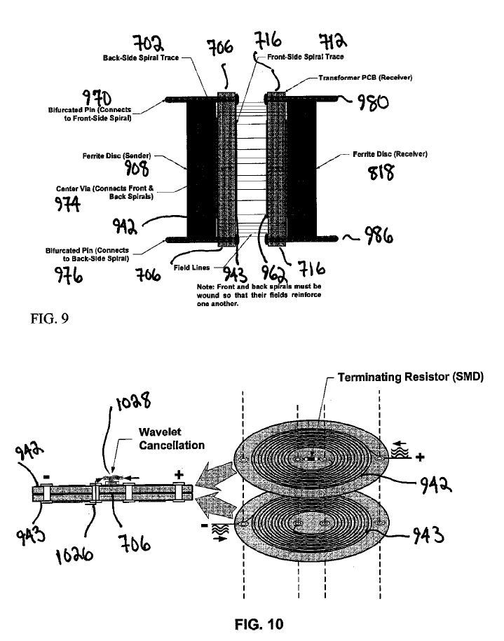

The contactless data communication coupler system accomplishes the direct communication of 100-Mb Ethernet baseband signals across a train coupler by means of a loosely coupled wide band pulse transformer that operates over an air gap. FIG. 7 is a front view illustrating one embodiment of the sender 702 and receiver 712. The primary winding 704 resides in the sending unit, located on a first train car 1, and the secondary winding 714 is contained in the receiving unit, located on a second train car. The primary winding is on and/or within a substrate 706 and in one embodiment is generally circular. In one embodiment, the primary winding 704 has two layers (shown in further detail in FIG. 9 below), with 11 turns per layer, where one layer is formed on top of the other layer in substantially power planes forming two planar windings disposed on and/or within the substrate 706 which are formed so as to neutralize transmission line resonances due to distributed capacitance and inductance of the planar windings. Further the primary winding has a termination resistor 708 of approximately 110 ohms.

In one embodiment, the secondary winding is 714 is shown with one winding in one layer with 7 turns. It should be noted for both the primary 704 and secondary winding 714 that other geometries, other number of turns and the other number of layers that neutralize transmission line resonances due to distributed capacitance and inductance of the planar windings are within the true scope and spirit of the present invention.

FIG. 8 is side view of the receiver printed circuit board and the sender printed circuit board of FIG. 7 according to the present invention. The substrate 706 of the sender 702 and the substrate 716 of the receive 712 are shown separated by an air gap 820 illustrates one embodiment of the sender 702 and receiver 712. The sender 702 is couple to a circuit board 802 and like wise the receiver is coupled to a circuit board 812. A ferrite discs 808 and 818 are placed beneath the substrate 706 of sender 702 and substrate 716 of receiver 712. The present invention has been shown to work advantageously with an air gap 820 to generate field 852 between sender 702 and receiver 712 ranges from 0.01″ to 0.150″ but other ranges are possible for different bandwidths.

The purpose of the ferrite is to straighten the flux lines, increase the inductance by a slight margin, and prevent stray magnetic coupling to nearby circuits within the sender or receiver housing. The exact properties of the ferrite are of minor importance, since the air gap accounts for about 80% of the magnetic circuit reluctance. Nevertheless, a good pulse-transformer ferrite should be chosen. The material used in one embodiment of the present invention is a nickel-zinc ferrite with an initial permeability of approximately 1300 at 50 kHz, 100 at 100 MHz, and 10 at 1 GHz. The Q (an inverse measure of lossiness) ranges from 23 at 50 kHz to 0.32 at 100 MHz. The present invention has been shown to work advantageously with an air gap 1020 to generate field 1052 between sender 702 and receiver 712 ranges from 0.01″ to 0.150″ but other ranges are possible for different bandwidths.

Overcoming Inherent Limitations in an Air Gap Pulse Transformer

The present invention overcomes problems associated with transferring a wideband pulse train across a loosely coupled transformer including:
1) resonance distortion caused by wavefront reflections within the equivalent transmission line represented by the winding;
2) frequency distortion caused by the limited inductance available from a small winding with substantial air gap.

In one embodiment, to push the resonant oscillations of the transformer windings above the signal band, thus mitigating resonance distortion above, the total length of the primary winding 704 and secondary winding 714 conductor is made as short as possible. The challenge with making the conductor short is a limitation on inductance, which exacerbates frequency distortion. For example, a typical packaged Ethernet transformer has a minimum primary inductance of about 350 μH. The loosely coupled wide band pulse transformer of the present invention uses less than 4 μH in the primary and less than 400 μH in the secondary. Low inductance produces poor low-frequency response, which manifests itself as an increase in baseline wander. Raising the inductance lowers the quarter-wave resonant frequency of the winding, aggravating the high-frequency distortion caused by reflected pulse edges. To overcome these interrelated phenomena, the present invention uses the following techniques.

As described above in FIG. 7 the primary winding 704 consists of two spiral-wound layers with the same number of turns in each to reinforce their electromagnetic fields from one another. In FIG. 9 show is a side view of the sender 902 and receiver 912 of FIG. 9. The two layers 942 and 944 disposed on the substrate 906 are joined at their centers through the center via 974.

A ferrite backstop or ferrite disc 808 is disposed underneath the windings 942 and 944 on the sender 902 and a ferrite disc 988 is disposed underneath the winding 820 on the receiver 912. A set of pins 970 and 976 on the sender 902 and a set of pins 986 on the receiver 912 electrically couple the to the respective printed circuit boards 802 and 804 of FIG. 8. At the joining point between the two planar winding layers, which represents the midpoint of the total winding, a resistor of a certain value is inserted. This value is described further below. This resistor effectively terminates the nonuniform distributed transmission line formed by the winding layers. Because the receive amplifier does not have an infinite input impedance, a step-down design in which the secondary consists of a single winding layer without a termination resistor. The self-resonance of this secondary is about 1 GHz, well above the signal band, and the source impedance presented to the amplifier input terminals is low enough that the high-frequency response is not unduly impacted by the amplifier's input capacitance.

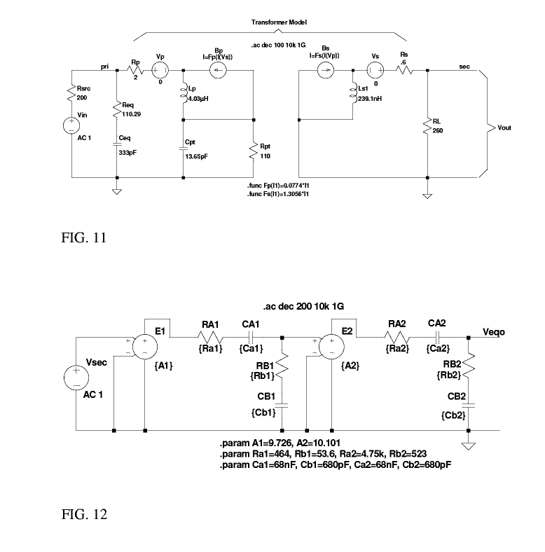

FIG. 11 a perspective view of FIGS. 6 and 9 illustrating how the two-layer printed spiral winding of the sending unit cause wavelet cancellation at the midpoint where a resistor 828 is disposed. In this case, the center printed circuit “via” 826 connecting the top and bottom circuit layers represents the midpoint of the winding and corresponds to the terminal shunt of the equivalent transmission line.

An additional load impedance of a few hundred ohms in one embodiment is placed across the secondary winding terminals to provide additional damping for the primary. If this load resistance is too low, the high-frequency performance of the system will suffer. If it is too high, there may be some residual ringing even with the terminating resistor added to the primary.

A series RC network should be added across the primary to equalize the load impedance presented to the send amplifier across the band of interest. Analysis shows that the load impedance seen by the amplifier can be made purely resistive by the proper choice of circuit values.

An equalizing network must be added on the receive side of the link to correct the frequency response of the system. The low-inductance transformer is essentially a high-pass device, and the low-frequency end must be boosted to provide an overall flat response from 50 kHz to 180 MHz. This corrected performance matches closely that of a packaged Ethernet transformer. The low end of the spectrum carries little information, but failing to restore the amplitude of these frequencies increases the rate of baseline wander to a level that cannot be corrected by the Ethernet PHY to which the signal is ultimately delivered.

Value for the Winding Termination Resistor

The value of the primary winding termination resistor can be calculated by the formula

$${R}_{t} = \frac{{t}_{p}}{C} , \qquad ( 1 )$$

where tₚ stands for the wave propagation time along the primary conductor from either lead terminal to the winding midpoint and C for the aggregate interlayer capacitance. The propagation time can be calculated as

$${t}_{p} = \sqrt{{μ}_{r} {ɛ}_{r}} \frac{{l}_{t}}{c} , \qquad ( 2 )$$

where lₜ is the conductor length for one of the spiral layers, c is the speed of light in vacuum, and εᵣ is the relative dielectric permittivity of the winding substrate. The relative permeability factor μᵣ would be unity if it were not for the nearby presence of the ferrite, which exerts a drag on the propagating wavefront. A full magnetic field analysis is necessary to determine the appropriate value of μᵣ, a description of which lies outside the scope of this document. The aggregate capacitance C can easily be measured, or, alternatively, calculated from the conductor geometry and the dielectric constant of the medium. The resistor has a value determined by an aggregate capacitance between the planar windings and a signal propagation delay along the planar windings by measuring a terminal of one of the planar windings.

Equalization of the Primary Input Admittance

It can be shown that the admittance presented at the primary terminals of the loaded transformer may be expressed in the form

$${Y}_{pp} = {K}_{pp} \frac{s - {s}_{0}}{( s - {s}_{1} ) ( s - {s}_{2} )} , \qquad ( 3 )$$

where s₀, s₁, and s₂ are negative real cardinal frequencies obtained by a thorough analysis of the transformer equivalent-circuit. Kₚₚ is a real factor that emergences from the same investigation. By adding a series RC network across the winding terminals, the total admittance can be rendered purely resistive if the resistor and capacitor values are chosen according to the formulas

$$\begin{matrix}{R}_{eq} = - \frac{1}{{K}_{pp}} \frac{{s}_{1} ( {s}_{2} - {s}_{1} )}{{s}_{0} - {s}_{1}} , & ( 4 ) \\ {C}_{eq} = - \frac{1}{{R}_{eq} {s}_{1}} . & ( 5 )\end{matrix}$$

FIG. 11 shows a low- to mid-frequency equivalent circuit of the transformer with the admittance equalization network added.

Equalization of the System Gain

Equalization of the system gain, with low-frequency restoration, is accomplished by means of two cascaded amplifier stages incorporating RC networks designed to shift the poles of the system transfer function. A fairly complex program is used to calculate the resistor and capacitor values required to achieve a maximally-flat step response in the time domain. This method uses a least-squares approach, resulting in component values for which the gain sensitivity functions are parabolic i.e. quadratic rather than linear. Accordingly, the equalizer EQ1 411 of FIG. 4 in the base unit 204 includes pole and zero distribution to provide an amplitude sensitivity to component and transformer parameter variations that is a quadratic rather than a linear function. Capacitor tolerances and transformer parameter variations are therefore less critical than they might be if such an optimization method were not used. FIG. 8 shows the general circuit topology.

Nonlimiting Examples

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The method as described above is used in the fabrication of integrated circuit chips.

The resulting integrated circuit chips can be distributed by the fabricator in raw wafer form (that is, as a single wafer that has multiple unpackaged chips), as a bare chip, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard, or other input device, and a central processor.

Although a specific embodiment of the invention has been disclosed, it will be understood by those having skill in the art that changes can be made to this specific embodiment without departing from the spirit and scope of the invention. The scope of the invention is not to be restricted, therefore, to the specific embodiment, and it is intended that the appended claims cover any and all such applications, modifications, and embodiments within the scope of the present invention.

What is claimed is:

1. A non-contact electromagnetic data connection comprising:
a first substrate; and
a loosely coupled wide band pulse transformer for transmitting data over an air gap separating a primary winding from a secondary winding of the transformer, wherein the primary winding of the transformer includes at least two planar windings formed in parallel planes upon and/or within the first substrate for facilitating a neutralization of transmission line resonances due to distributed capacitance and inductance of the planar windings.

2. The non-contact magnetic data connection of claim 1, wherein there are exactly two planar windings.

3. The non-contact magnetic data connection of claim 1, wherein each of the planar windings are formed with an identical number of turns.

4. The non-contact magnetic data connection of claim 1, wherein the secondary winding includes a single planar winding formed upon and/or within a second substrate, wherein the second substrate is separated from the first substrate by the air gap.

5. The non-contact magnetic data connection of claim 1, further comprising:
at least one resistor placed substantially at a geometric center of the windings in order to neutralize transmission line resonances arising due to distributed inductance and capacitance of the planar windings.

6. The non-contact magnetic data connection of claim 4, further comprising:
at least one resistor placed substantially at a geometric center of the single planar winding of the secondary winding.

7. The non-contact magnetic data connection of claim 5, wherein the resistor has a value determined by an aggregate capacitance between the planar windings and a signal propagation delay along the planar windings.

8. The non-contact magnetic data connection of claim 7, wherein the value is determined by the aggregate capacitance between the resistor and a signal propagation delay along the planar windings by measuring a terminal of one of the planar windings.

9. The non-contact magnetic data connection of claim 1, wherein the planar windings are placed in close proximity to a ferrite backstop to shape a magnetic field produced by the primary winding.

10. The non-contact magnetic data connection of claim 1, further comprising:
an amplifier electrically connected in close proximity to the primary winding to amplify a signal representing data from a base unit prior to the primary winding so as to permit the base unit to be physically separated from the primary winding.

11. The non-contact magnetic data connection of claim 10, further comprising:
an admittance equalizer disposed between the amplifier and the primary winding to equalize an admittance in order to present a resistive load to the amplifier.

12. The non-contact magnetic data connection of claim 1, further comprising:
a metallic housing enclosing the primary transformer except at a region of the primary transformer from which a magnetic field is generated.

11. The non-contact magnetic data connection of claim 12, further comprising:
a serrated ground ring electrically connected to the metallic housing and to a shield of a cable carrying the data from a base unit to the primary transformer.

14. The non-contact magnetic data connection of claim 11, further comprising:
a balanced differential pair of conductors in the cable.

15. The non-contact magnetic data connection of claim 14, further comprising:
a power source providing a common-mode DC voltage to the balanced differential pair.

16. The non-contact magnetic data connection of claim 1, further comprising:
a base unit with a equalizer to modify a signal induced in a secondary winding by the primary winding, wherein the equalizer provides compensation for a frequency response of the transformer using a multi-stage passive filter with an associated amplifier to overcome a natural insertion loss of the filter.

17. The non-contact magnetic data connection of claim 16, wherein the equalizer includes pole and zero distribution to provide an amplitude sensitivity to component and transformer parameter variations that is a quadratic rather than a linear function.

18. The non-contact magnetic data connection of claim 10, further comprising:
an automatic gain control electrically connected in close proximity to the base unit that regulates a signal amplitude presented to a network interface device from the base unit

19. The non-contact magnetic data connection of claim 18, further comprising:
a local area network connection electrically connected in close proximity to the base unit that provides a point of interconnection between a network and the base unit.

20. A non-contact electromagnetic data connection comprising:
a first substrate with a primary winding and a second substrate with a secondary winding separated by an air gap to form a loosely coupled wide band pulse transformer for transmitting data over the air gap, wherein the primary winding of the transformer includes at least two planar windings formed with an identical number of turns and in parallel planes upon and/or within the first substrate for facilitating a neutralization of transmission line resonances due to distributed capacitance and inductance of the planar windings;
at least one resistor placed substantially at a geometric center of the planar windings in order to neutralize transmission line resonances arising due to distributed inductance and capacitance of the planar windings.
